(19) United States
(12) Patent Application Publication
(10) Pub. No.: US 2024/0239303 A1
(43) Pub. Date: Jul. 18, 2024

(54) SYSTEMS AND METHODS FOR CONTROLLING ACCESS TO ELECTRICAL POWER OUTLETS IN A VEHICLE

(71) Applicant: Ford Global Technologies, LLC, Dearborn, MI (US)

(72) Inventors: Stuart C. Salter, White Lake, MI (US); Vyas Shenoy, Canton, MI (US); Brendan Diamond, Grosse Pointe, MI (US); John Robert Van Wiemeersch, Novi, MI (US); David Celinske, Wolverine Lake, MI (US)

(73) Assignee: Ford Global Technologies, LLC, Dearborn, MI (US)

(21) Appl. No.: 18/153,418

(22) Filed: Jan. 12, 2023

(51) Int. Cl. B60R 25/40; B60R 16/00; B60R 16/033; B60R 25/30; G01R 31/382

(52) U.S. Cl. CPC B60R 25/403; B60R 16/005; B60R 16/033; B60R 25/305; G01R 31/382

(57) ABSTRACT

The disclosure is generally directed to systems and methods for controlling access to electrical power outlets in a vehicle. An example method executed by a processor may include determining that the vehicle is in a key-off state and detecting a door of the vehicle being opened (or detecting the door being unlocked by use of a passive entry device) when the vehicle is in the key-off state. A time period may be provided after the first door is opened or unlocked so as to allow an individual to operate a switch for coupling an electrical power source to an electrical power outlet in the vehicle. The electrical power outlet may be disconnected from the electrical power source based on detecting a failure of the individual to operate the switch within the time period and/or based on detecting a movement of the individual outside a boundary defined around the vehicle.

### BACKGROUND

Some vehicles are equipped with electrical power outlets that can be used for powering various devices, such as lights, personal devices, and power tools. It is desirable to control access to power outlets in a vehicle address in order to prevent unauthorized users from using the electrical power outlets.

### BRIEF DESCRIPTION OF THE DRAWINGS

A detailed description is set forth below with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 shows an example vehicle that includes an electrical power outlet controller in accordance with an embodiment of the disclosure.

FIG. 2 illustrates an example configuration that may be associated with an electrical power outlet controller system in accordance with an embodiment of the disclosure.

FIG. 3 shows a flowchart of an example method to operate an electrical power outlet controller system in accordance with an embodiment of the disclosure.

FIG. 4 shows some example components that can be included in a vehicle in accordance with an embodiment of the disclosure.

### DETAILED DESCRIPTION

### Overview

In terms of a general overview, embodiments described in this disclosure are generally directed to systems and methods for controlling access to power outlets in a vehicle. An example method executed by a processor of an electrical power outlet controller in a vehicle includes determining that the vehicle is in a key-off state and further includes detecting a door of the vehicle being opened (or detecting the door being unlocked by use of a passive entry device). A time period may be provided by the processor to allow an individual to energize an electrical power outlet in the vehicle after the first door is opened or unlocked and the vehicle is in the key-off state. The electrical power outlet may be energized by manually operating a switch to couple an electrical power source to the electrical power outlet. The example method may further include disconnecting the electrical power outlet from the electrical power source based on at least one of detecting a failure of the individual to operate the switch within the time period or detecting a movement of the individual outside a boundary defined around the vehicle.

### Illustrative Embodiments

The disclosure will be described more fully hereinafter with reference to the accompanying drawings, in which example embodiments of the disclosure are shown. This disclosure may however, be embodied in many different forms and should not be construed as limited to the example embodiments set forth herein. It will be apparent to persons skilled in the relevant art that various changes in form and detail can be made to various embodiments without departing from the spirit and scope of the present disclosure. Thus, the breadth and scope of the present disclosure should not be limited by any of the above-described example embodiments but should be defined only in accordance with the following claims and their equivalents. The description below has been presented for the purposes of illustration and is not intended to be exhaustive or to be limited to the precise form disclosed. It should be understood that alternate implementations may be used in any combination desired to form additional hybrid implementations of the present disclosure. For example, any of the functionality described with respect to a particular device or component may be performed by another device or component. Furthermore, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments.

Certain words and phrases are used herein solely for convenience and such words and terms should be interpreted as referring to various objects and actions that are generally understood in various forms and equivalencies by persons of ordinary skill in the art. For example, the word “information” as used herein pertains to any of various forms of data that can be processed by a processor (digital data, digital images, detector signals, etc.). The word “image” as used herein encompasses one or more images in one or more forms. Thus, for example, a description herein of an action associated with an “image” must be understood to indicate an action performed upon a single image in some scenarios and upon multiple images in some other scenarios. The multiple images can be included in various forms such as, for example, in the form of a video clip, and/or in the form of real-time video.

The word “detector,” which may be used interchangeably with the word “sensor,” as used herein refers to any device than may be used to obtain information about an object, to detect the presence of an object, and/or to detect actions performed by individuals. The word “object” and the word “item” are used in this disclosure in an interchangeable manner. The word “vehicle” as used in this disclosure can pertain to any one of various types of vehicles such as cars, vans, sports utility vehicles, trucks, electric vehicles, gasoline vehicles, and hybrid vehicles.

It must be understood that words such as “implementation,” “application,” “scenario,” “case,” and “situation” as used herein are an abbreviated version of the phrase “In an example (“implementation,” “application,” “scenario,” “case,” “approach,” and “situation”) in accordance with the disclosure.” It must also be understood that the word “example” as used herein is intended to be non-exclusionary and non-limiting in nature.

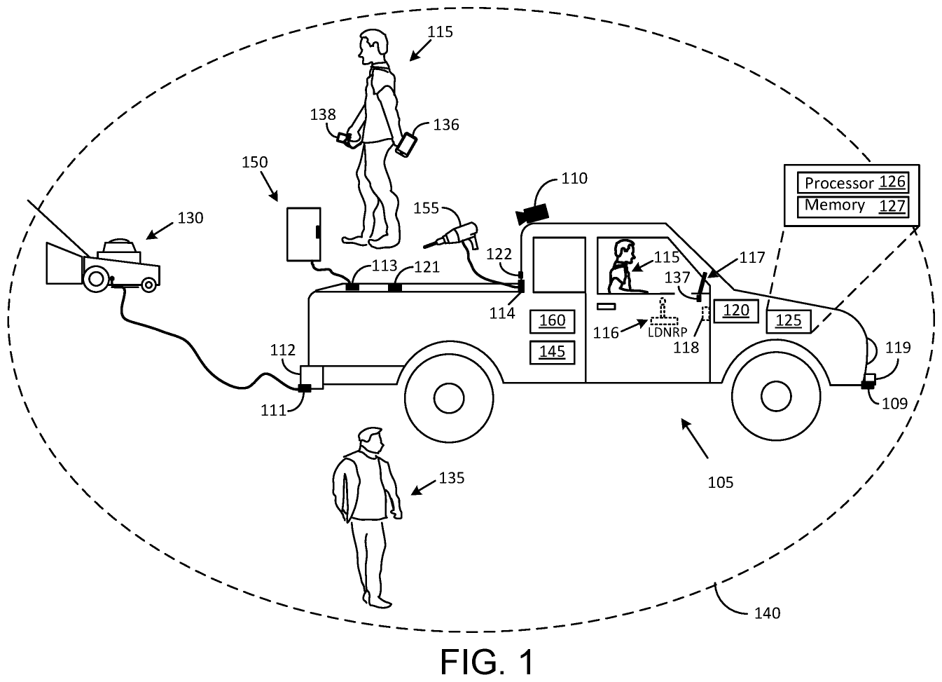

FIG. 1 shows a vehicle 105 that includes an electrical power outlet controller system 125 in accordance with an embodiment of the disclosure. The vehicle 105 may further include components such as, for example, a vehicle computer 120, an infotainment system 117, a detector system 160, and an electrical power source 145. These components may be communicatively coupled to the electrical power outlet controller system 125 via a wired communication system and/or a wireless communication system. The vehicle 105 may further include one or more electrical power outlets that are configured to offer access to electrical power provided by the electrical power source 145. The electrical power source 145 may be controlled by the electrical power outlet controller system 125 in accordance with the disclosure.

In the illustrated example, the vehicle 105 is a truck containing a cargo bed on which items can be placed and the description herein pertains to various systems and methods of operation associated with the truck. However, it must be understood that the systems and methods of operation described herein are equally applicable to various other types of vehicles (sedan, van, sports utility vehicle, forklift, etc.). Thus, for example, a description pertaining to characteristics and operations of an electrical power outlet provided in the truck that is illustrated in FIG. 1 is equally applicable to an electrical power outlet provided in a van, a sedan, or a forklift, for example. Furthermore, in the illustrated example, the vehicle 105 is a driver-operated vehicle. However, the description provided herein is equally applicable to an autonomous vehicle and the various actions described herein with respect to a driver 115 of the vehicle 105 may be carried out by any person seated in the vehicle 105 and/or by a controller system (not shown) of the autonomous vehicle. As illustrated, in a first example situation, the driver 115 may be seated inside the vehicle 105 and in a second example situation, the driver 115 may be moving around outside the vehicle 105 (such as, for example, when plugging an object into an electrical power outlet provided on the vehicle 105 outside the cabin or when walking away from the vehicle 105).

The vehicle computer 120 may perform various functions of the vehicle 105, such as, for example, controlling engine operations (fuel injection, speed control, emissions control, braking, etc.), managing climate controls (air conditioning, heating etc.), activating airbags, and issuing warnings (check engine light, bulb failure, low tire pressure, etc.). The vehicle computer 120 may also provide various types of information to the electrical power outlet controller system 125, such as, for example, information pertaining to operations associated with the vehicle 105 (key-off status, key-on status, speed, movement status, parked status, etc.).

In an example implementation, the vehicle computer 120 may provide to the electrical power outlet controller system 125, status information of various objects in the vehicle 105, including, a key-on/key-off status of the vehicle 105. A key-on status is typically associated with a key being inserted into an ignition lock of the vehicle 105 and rotated in order to either start an engine of the vehicle 105 or to turn on accessories (such as the infotainment system 117) without starting the engine. A key-off status is typically associated with the key being removed from the ignition lock. It must be understood that the description provided herein with respect to a key and particularly, to a key-on/key-off status, is equally applicable to a push-button that may be used to perform similar functions (starting an engine of a gasoline-operated vehicle, starting an electric motor of a battery electric vehicle, turning on accessories in a vehicle, etc.). Thus, for example, a description herein with respect to a key-off status of the vehicle 105 is equally applicable to either a physical key being removed from an ignition lock of the vehicle 105 or an inactivated push-button of the vehicle 105. The physical key or push-button is referred to hereinafter generically as a vehicle key 137.

In another example implementation, a key-on/key-off status of the vehicle 105 may be determined by the electrical power outlet controller system 125 based on evaluating one or more images provided to the electrical power outlet controller system 125 by one or more cameras (not shown) located in a cabin area of the vehicle 105.

The infotainment system 117 can be an integrated unit that includes various components such as a radio, a display screen, a speaker, and other components such as a USB access port, a Bluetooth® system, Ultra-Wide Band (UWB) system, and a global positioning satellite (GPS) navigation system. In an example implementation, the display screen may include a graphical user interface (GUI) for use by an occupant of the vehicle 105. The GUI may be used for various purposes such as to enter commands for interacting with the GPS navigation system, to select a phone number for making a phone call, and to make a song selection. In an example implementation, the GUI may be used by the driver 115 of the vehicle 105 to communicate with the electrical power outlet controller system 125 in accordance with the disclosure.

The detector system 160 can include one or more of various types of detection devices such as, for example, a door opening detector, a door unlocking detector, a door unlatching detector, a presence detector, and a movement detector. The detection devices may include, for example, a magnetic sensor, a radar detector, a sonar detector, a light detection and ranging (LIDAR) detector, and/or an infrared detector. The detector system 160 may further include image capture devices such as, for example, one or more cameras.

In the illustrated implementation, the camera 110 is an example device that can be used to provide information to the electrical power outlet controller system 125 in the form of images. In other implementations, additional cameras and/or other types of devices may be used to provide information to the electrical power outlet controller system 125. The images provided by the cameras may be evaluated by the electrical power outlet controller system 125 for various purposes. In an example scenario, the electrical power outlet controller system 125 may evaluate images provided by the camera 110 to detect a presence of one or more individuals near the vehicle 105 and/or to detect objects that may be coupled to electrical power outlets of the vehicle 105. The electrical power outlet controller system 125 may execute various actions upon one or more electrical power outlets provided in the vehicle 105 based on evaluating such images.

The example electrical power outlets provided in the vehicle 105 include a first set of electrical power outlets that are located in a cabin area of the vehicle 105 such as, for example, an electrical power outlet 118 located on a lower portion of an instrument console. The vehicle 105 further includes a second set of electrical power outlets that are located outside the cabin area, such as, for example, an electrical power outlet 109, an electrical power outlet 114, an electrical power outlet 113, an electrical power outlet 121, and an electrical power outlet 111. The electrical power outlets may have various form factors and characteristics (two-hole socket, three-hole socket, US-type layout, European-style layout, etc.) and may be mounted upon various parts of the vehicle 105 such as, for example, a bumper, a grille, a tailgate, a roof, a chassis, or a body panel.

In the illustrated example, the electrical power outlet 109 is located underneath a front bumper 119 of the vehicle 105, the electrical power outlet 114 is located on a body panel behind a cabin wall of the vehicle 105, the electrical power outlet 113 and the electrical power outlet 121 are located on a side panel of the cargo bed of the vehicle 105, and the electrical power outlet 111 is located behind or underneath a rear bumper 112 of the vehicle 105.

The electrical power source 145 can include any of various types of components that produce one or more of various types of voltages such as, for example, 5V DC, 12V DC, 110V AC, and 220V AC. In an example implementation, the electrical power source 145 can produce 5V DC that may be provided via the electrical power outlet 118 for use by an occupant of the vehicle 105 (the driver 115, for example). In an example scenario, the electrical power outlet 118 may be a USB socket. In another example implementation, the electrical power source 145 can include a battery that produces 12V DC. The 12V DC voltage may be provided for use by the occupant of the vehicle 105 via the electrical power outlet 118, which may be provided in the form of a cigarette lighter socket, for example. Similar voltages, or other voltages, may be provided via other electrical power outlets in the cabin of the vehicle 105 and outside the cabin of the vehicle 105.

In at least some cases, the electrical power outlets provided outside the cabin of the vehicle 105 may be configured for some types of use that may be similar to those that are applicable to the electrical power outlets in the cabin of the vehicle 105. For example, the electrical power outlet 121 may be configured for charging a personal device such as, for example, a personal device 136 carried by the driver 115. The personal device 136 can be any of various devices such as, for example, a smartphone, a smartwatch, or a smart wearable that are configured to communicate with the vehicle computer 120 and/or the electrical power outlet controller system 125. In an example embodiment, the personal device 136 is configured as a phone-as-a-key (PaaK) device that can be used to perform various actions such as, for example, start an engine of the vehicle 105, lock/unlock a door of the vehicle 105, and transmit/receive information from the vehicle computer 120 and/or the electrical power outlet controller system 125. The driver 115 may also carry a key fob 138 that may be used to perform various actions such as, for example, start an engine of the vehicle 105 and lock/unlock a door of the vehicle 105.

In some other cases, the electrical power outlets provided outside the cabin of the vehicle 105 may be configured for some types of use that may be different from those applicable to the electrical power outlets inside the cabin of the vehicle 105. For example, in one implementation, the electrical power outlet 111 located behind or underneath the rear bumper 112 of the vehicle 105, may be a 3-hole electrical socket that supplies 110V AC voltage for operating a component such as a lawn mower 130 and the electrical power outlet 118 located in the cabin area of the vehicle 105 can be a USB connector that allows charging of a personal device 136 (a smartphone, for example). The 110V AC power may also be additionally supplied via other electrical power outlets for operating various other types of items such as, for example, a portable refrigerator 150 that is shown plugged into the electrical power outlet 113 and a hand drill 155 that is shown plugged into the electrical power outlet 114.

Some of the items that are plugged into the electrical power outlets of the vehicle 105 are portable and may be transported in the vehicle 105 while plugged into an electrical power outlet of the vehicle 105. One example of such an item is the hand drill 155 that is plugged into the electrical power outlet 114. However, it may be undesirable to transport some other items while plugged into an electrical power outlet of the vehicle 105. One example of such an item is the lawn mower 130 that is plugged into the electrical power outlet 111.

The electrical power outlet controller system 125 is configured to perform various operations in accordance with the disclosure such as, for example, administering, monitoring, and controlling access to the various electrical power outlets provided in the vehicle 105. More particularly, a processor 126 of the electrical power outlet controller system 125 is configured to access a memory 127 and execute computer-executable instructions stored in the memory 127 for executing operations such as, for example, starting a timer upon determining that the vehicle 105 is in a key-off state and the driver 115 is intending to use one of the electrical power outlets that are located outside the cabin of the vehicle 105. The timer provides a time-out functionality that allows the driver 115 to get out of the cabin of the vehicle 105 and activate a power outlet activation switch 122 to energize the electrical power outlet 114, for example. The power outlet activation switch 122 can be any of various types of mechanical, electrical, or electronic switches such as for example a push-button switch, a toggle switch, and a soft switch (on the personal device 136, for example).

In an example implementation, the timer may be set to time out after a preset time period (such as, for example, one minute). In another example implementation, the timer may be set to time out after a user-definable time period (two minutes, for example). In yet another implementation, the timer may be set to provide a time out that expires based on an explicit action taken by the user (such as, for example, an over-ride instruction provided by the driver 115 to the electrical power outlet controller system 125 via use of the GUI of the infotainment system 117 or via the personal device 136).

Activating the power outlet activation switch 122 enables electrical power to be coupled from the electrical power source 145 to the electrical power outlet 114. If the driver 115 fails to activate the power outlet activation switch 122 before expiry of the timer, the electrical power outlet controller system 125 ensures that the electrical power outlet 114 (and other electrical power outlets outside the cabin of the vehicle 105) is placed in an unpowered state. Placing the various electrical power outlets in an unpowered state prevents misuse of the electrical power outlets by undesirable entities such as, for example, an individual 135 who may seek to slyly use one of the electrical power outlets to charge his/her smartphone.

In an example implementation, the electrical power outlet controller system 125 may be configured to detect objects that may be present inside an example boundary 140. Configuring the electrical power outlet controller system 125 for this operation can include defining the boundary 140 via, for example, entering instructions into the GUI of the infotainment system 117 or storing information in the memory 127 of the electrical power outlet controller system 125. In the illustrated example scenario, the boundary 140 has an oval shape. However, in other scenarios, the boundary 140 can have other shapes (square, rectangular, circular, etc.). A radius of the boundary 140, when having a circular shape, may be selected to correspond to a threshold distance that may be definable by any of various entities such as, for example, the driver 115. In an example implementation, the boundary 140 can be a geofence.

In lieu of using the timer functionality, in another example implementation, the processor 126 of the electrical power outlet controller system 125 may evaluate images captured by use of one or more cameras such as, for example, the camera 110 when the vehicle 105 is in a key-off state. In an example scenario, the processor 126 may evaluate the images and detect the driver 115 moving towards the vehicle 105 and may also, in some cases, determine an identity of the driver 115 (using facial recognition, for example). The processor 126 may then authorize the use of some (or all) electrical power outlets by the driver 115. In another example scenario, the processor 126 may evaluate the images and detect the individual 135 located near the vehicle 105 and/or inside the boundary 140. The processor 126 may determine that the individual 135 is not authorized to use any of the electrical power outlets in the vehicle 105 and may disconnect electrical power from all the electrical power outlets.

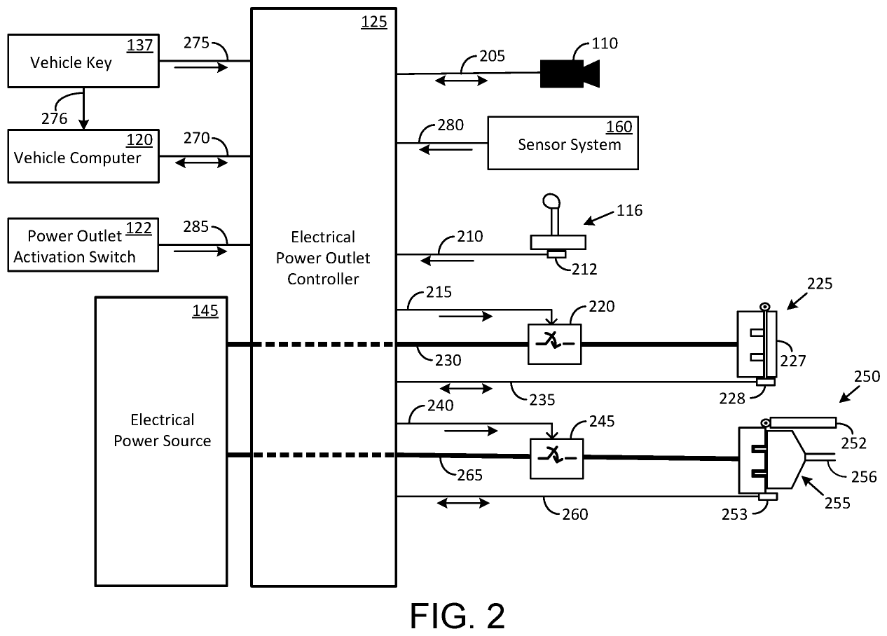

FIG. 2 illustrates an example configuration that may be associated with the electrical power outlet controller system 125 in accordance with an embodiment of the disclosure. In this example configuration, the electrical power outlet controller system 125 is shown controlling power provided to two example electrical power outlets - an electrical power outlet 225 and an electrical power outlet 250. However, it must be understood that the description provided herein is equally applicable to configurations where the electrical power outlet controller system 125 controls power provided to a single electrical power outlet or to more than two electrical power outlets. The electrical power outlets can be of various types such as, for example, the various electrical power outlets described above with reference to FIG. 1

Electrical power is provided to the two example electrical power outlets by the electrical power source 145. As indicated above, the electrical power source 145 can include any of various types of components that can produce various types of voltages such as, for example, an AC power supply, a DC power supply, an DC-to-AC converter, and/or a battery. The various components may provide one or more voltages such as, for example, 5V DC, 12V DC, 110V AC, and 220V AC.

In the illustrated configuration, various other objects are coupled to the electrical power outlet controller system 125. The objects can include, for example, the camera 110, the vehicle computer 120, the vehicle key 137, the detector system 160, the power outlet activation switch 122, a detector 212 coupled to the drive selector 116, a switch 220, a detector 228, a switch 245, and a detector 253. The camera 110 may be coupled to the electrical power outlet controller system 125 via a bidirectional link 205 that can be implemented by use of any of various wired and/or wireless media such as, for example, a coaxial cable, an optical fiber, and/or a WiFi link. The bidirectional link 205 may be used to convey commands (such as, for example, an image capture command) from the electrical power outlet controller system 125 to the camera 110 and for conveying images in the opposite direction from the camera 110 to the electrical power outlet controller system 125.

The vehicle computer 120 may be coupled to the electrical power outlet controller system 125 via a bidirectional link 270 that can be implemented by use of any of various wired and/or wireless media such as, for example, a coaxial cable, an optical fiber, and/or a WiFi link. The bidirectional link 270 may be used to convey requests (such as, for example, a request for key-off status, engine operating information, or vehicle movement status) from the electrical power outlet controller system 125 to the vehicle computer 120 and for conveying requested information in the opposite direction from the vehicle computer 120 to the electrical power outlet controller system 125.

The vehicle key 137 may be coupled to the vehicle computer 120 via a wired link 276 and to the electrical power outlet controller system 125 via a link 275 that can be implemented by use of any of various wired and/or wireless media such as, for example, a coaxial cable, an optical fiber, and/or a WiFi link. The link 275 may convey to the electrical power outlet controller system 125, status information of the vehicle key 137 (key-on state, key-off state, etc.). The link 276 may convey signals to the vehicle computer 120 to start an engine (or motor) of the vehicle 105, shut-off the engine (or motor), turn on accessories in the vehicle 105, and turn off accessories in the vehicle 105.

The power outlet activation switch 122 may be coupled to the electrical power outlet controller system 125 via a link 285, which in an example implementation, is a wired link. The link 285 may be used to convey signals to the electrical power outlet controller system 125 to couple power from the electrical power source 145 to one or more electrical power outlets (energizing the one or more electrical power outlets) decouple the electrical power source 145 from one or more of the electrical power outlets.

The detector system 160 may be coupled to the electrical power outlet controller system 125 via a link 280 that can be implemented by use of any of various wired and/or wireless media such as, for example, a coaxial cable, an optical fiber, and/or a WiFi link.

The detector 212 that is coupled to the drive selector 116 is configured to detect a position of a lever of the drive selector 116 (“L”, “D”, “N”, “R”, or “P” positions). The detector 212 is coupled to the electrical power outlet controller system 125 via a link 210 that can be implemented by use of any of various wired and/or wireless media such as, for example, a coaxial cable, an optical fiber, and/or a WiFi link. The link 210 may be used to convey position information of the lever of the drive selector 116 to the electrical power outlet controller system 125. In an example implementation, the electrical power outlet controller system 125 may use the information provided by the detector 212 to complement, supplement, replace, or confirm information obtained via images captured by a camera and/or information provided by the vehicle computer 120 and/or the vehicle key 137, to determine key-on/key-off status of the vehicle 105.

The switch 220 can be any of various devices such as, for example, a manually-operable switch, a relay, or a circuit breaker, and is configured to connect or disconnect electrical power carried on a power line 230 from the electrical power source 145 to the electrical power outlet 225. The electrical power outlet controller system 125 can disconnect power to the electrical power outlet 225 by sending a first switch control signal (via a link 215) to the switch 220 that places the switch 220 in an open position. The electrical power outlet controller system 125 can reconnect power to the electrical power outlet 225 by sending a second switch control signal to the switch 220 (via the link 215) that places the switch 220 in a closed position.

The detector 228 is coupled to the electrical power outlet 225 in a configuration that allows the detector 228 to produce a first detection signal when a cover 227 that is attached to the electrical power outlet 225 is in an open position. The electrical contacts of the electrical power outlet 225 are exposed when the cover 227 is in the open position. When exposed, the electrical contacts allow an electrical connector (not shown) to be mated with the electrical power outlet 225.

The detector 228 is coupled to the electrical power outlet controller system 125 via a link 235 that can be implemented by use of any of various wired and/or wireless media such as, for example, a coaxial cable, an optical fiber, and/or a WiFi link. The link 235 may be used to convey a status information of the cover 227 (closed or open) to the electrical power outlet controller system 125. The link 235 may also be used by the electrical power outlet controller system 125 to transmit a signal for retaining the cover 227 in a closed position (or in an open position).

Retaining the cover 227 (and other such covers) in a closed position can prevent misuse of the electrical power outlet controller system 125 such as, for example, by the individual 135 shown in FIG. 1. In an example implementation, the electrical power outlet controller system 125 may either close or open the cover 227 based on a time delay such as, for example, the time-out period provided by the processor 126 after detecting a key-off status and a door opening/unlocking action in accordance with the disclosure.

In a first example operational scenario, the electrical power outlet controller system 125 obtains status information of the cover 227 from the detector 228. The cover 227 is in a closed condition in the illustrated example. At this time, the electrical power outlet controller system 125 may place the switch 220 in an open position so as to disconnect electrical power to the electrical power outlet 225.

In another example operational scenario, the electrical power outlet controller system 125 obtains status information of the cover 227 from a camera such as, for example, the camera 110 which may be configured to obtain an image of the electrical power outlet 225 and the cover 227. The electrical power outlet controller system 125 may evaluate the image and determine that the cover 227 is in a closed position. In this condition, the electrical power outlet controller system 125 may place the switch 220 in an open position so as to disconnect electrical power to the electrical power outlet 225.

In yet another example operational scenario, the electrical power outlet controller system 125 may include a current detecting device (not shown) that can identify a current flow in the power line 230. In the illustrated example, there is no current flow in the power line 230 because the electrical power outlet 225 is in an unused condition and the electrical power outlet controller system 125 may place the switch 220 in an open position.

The switch 245 may be similar to, or identical to the switch 220 described above, and is configured to disconnect electrical power provided from the electrical power source 145 and via the power line 265 to the electrical power outlet 250. The electrical power outlet controller system 125 can disconnect power to the electrical power outlet 250 by sending a first control signal to the switch 245 via a link 240 that places the switch 245 in an open position. The electrical power outlet controller system 125 can reconnect power to the electrical power outlet 250 by sending a second control signal via the link 240 to the switch 245 that places the switch 245 in a closed position.

The detector 253 is coupled to the electrical power outlet 250 in a configuration that allows the detector 253 to produce a first detection signal when a cover 252 that is attached to the electrical power outlet 250 is in an open position. The electrical contacts of the electrical power outlet 250 are exposed when the cover 252 is in the open position. When exposed, the electrical contacts allow an electrical connector 255 to be mated with the electrical power outlet 250.

The detector 253 is coupled to the electrical power outlet controller system 125 via a link 260 that can be implemented by use of any of various wired and/or wireless media such as, for example, a coaxial cable, an optical fiber, and/or a WiFi link. The link 260 may be used to convey a status information of the cover 252 (closed or open) to the electrical power outlet controller system 125.

In a first example operational scenario, the electrical power outlet controller system 125 obtains status information of the cover 252 from the detector 253, which in the illustrated example is in an open position. In this condition, the electrical power outlet controller system 125 may place the switch 220 in a closed position so as to provide electrical power to the electrical connector 255 that is mated with the electrical power outlet 250.

In another example operational scenario, the electrical power outlet controller system 125 obtains status information of the cover 252 from a camera such as, for example, the camera 110 which may be configured to obtain an image of the electrical power outlet 250 and the cover 252. The electrical power outlet controller system 125 may evaluate the image and determine that the cover 252 is in an open position and that no connector is mated to the electrical power outlet 250. At this time, the electrical power outlet controller system 125 may place the switch 220 in an open position so as to disconnect electrical power to the electrical power outlet 225. However, at another instant in time, the electrical power outlet controller system 125 may evaluate another image and determine that the electrical connector 255 is mated with the electrical power outlet 250. In this condition, the electrical power outlet controller system 125 places the switch 220 in a closed position so as to provide electrical power to the electrical connector 255.

In yet another example operational scenario, the electrical power outlet controller system 125 may include a current detecting device (not shown) that can identify a current flow in the power line 265. In the illustrated example, there may be current flow in the power line 230 because the electrical connector 255 is mated with the electrical power outlet 250 and a device may be drawing current via the electrical power cord 256 that is coupled to the electrical connector 255.

In an example implementation, the electrical power outlet controller system 125 may turn on (or turn off) power provided to an electrical power outlet based on detecting a hand gesture or a spoken command of an individual.

In another example implementation, the electrical power outlet controller system 125 may place all exterior electrical power outlets in an unpowered state under certain circumstances such as, for example, when no authorized individual is present in or around the vehicle 105, if no authorized device is present in the vehicle 105, and/or if no authorized device is present inside a perimeter area defined around the vehicle 105 (the boundary 140 shown in FIG. 1). One example of an authorized device is the personal device 136 shown in FIG. 1. The personal device 136 may be configured to perform certain operations related to the vehicle 105, such as, for example, starting the vehicle 105 from outside the vehicle 105 and/or maneuvering the vehicle 105 from outside the vehicle 105 (automatic parking, for example).

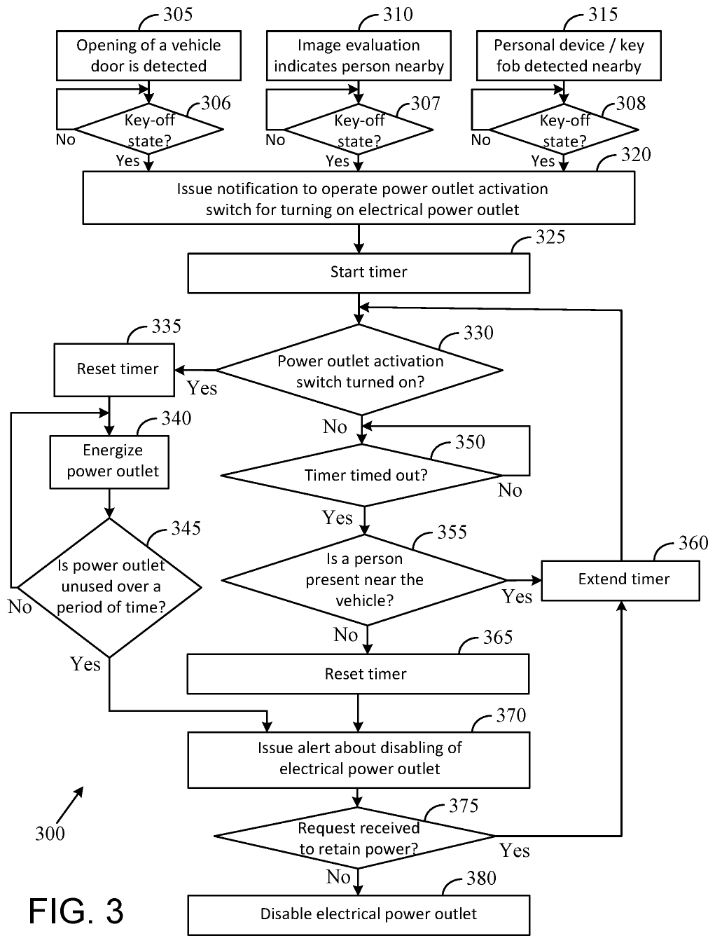

FIG. 3 shows a flowchart 300 of an example method to operate an electrical power outlet controller system in accordance with an embodiment of the disclosure. The flowchart 300 illustrates a sequence of operations that can be implemented in hardware, software, or a combination thereof. In the context of software, the operations represent computer-executable instructions stored on one or more non-transitory computer-readable media such as the memory 127 of the electrical power outlet controller system 125, that, when executed by one or more processors such as the processor 126 of the electrical power outlet controller system 125, perform the recited operations. Generally, computer-executable instructions include routines, programs, objects, components, data structures, and the like that perform particular functions or implement particular abstract data types. The order in which the operations are described is not intended to be construed as a limitation, and any number of the described operations may be carried out in a different order, omitted, combined in any order, and/or carried out in parallel.

Any of several actions may be carried out to initiate an operation that is indicated at block 320 and described below. One example action, which is indicated at block 305, is a detection of a door of a vehicle being opened. The detection may be carried out by a processor of an electrical power outlet controller system based on a signal received from a detector configured to detect opening of the door. At block 306, a determination is made whether the vehicle is in a key-off state. The determination may be made based on, for example, information received by the processor from a vehicle computer of the vehicle (vehicle computer 120, for example). If the vehicle is not in a key-off state, the processor continues to wait until the vehicle is placed in a key-off state. If the vehicle is in a key-off state, the processor executes the actions described below with reference to block 320 and subsequent blocks.

Another example action that is indicated at block 310 is detection of a person in the vicinity of the vehicle. In an example implementation, this action may be performed by the processor of the electrical power outlet controller system based on evaluating an image captured by a camera mounted on the vehicle. Evaluation of the image can include, for example, a determination whether the person is located inside a boundary or a geofence that may be defined around the vehicle. The boundary or geofence may be defined by various entities such as, for example, by a driver of the vehicle. At block 307, a determination is made whether the vehicle is in a key-off state. The determination may be made based on, for example, information received by the processor from a vehicle computer of the vehicle (vehicle computer 120, for example). If the vehicle is not in a key-off state, the processor continues to wait until the vehicle is placed in a key-off state. If the vehicle is in a key-off state, the processor executes the actions described below with reference to block 320 and subsequent blocks.

Another example action that is indicated at block 315 is detection of a personal device or a key fob in the vicinity of the vehicle. In an example implementation, this action may be performed by the processor of the electrical power outlet controller system based on evaluating an image captured by a camera mounted on the vehicle. Evaluation of the image can include, for example, a determination whether the personal device or key fob is located inside a boundary or a geofence that may be defined around the vehicle. The boundary or geofence may be defined by various entities such as, for example, by a driver of the vehicle. At block 308, a determination is made whether the vehicle is in a key-off state. The determination may be made based on, for example, information received by the processor from a vehicle computer of the vehicle (vehicle computer 120, for example). If the vehicle is not in a key-off state, the processor continues to wait until the vehicle is placed in a key-off state. If the vehicle is in a key-off state, the processor executes the actions described below with reference to block 320 and subsequent blocks.

At block 320, an action is taken in response to one or more of the actions described above with reference to block 306, block 307, and block 308. The action performed at block 320, which can be omitted in some implementations, pertains to issuing a notification (to a driver of the vehicle, for example), that a power activation switch has to be operated in order to energize one or more electrical power outlets provided in the vehicle. The description below refers to one electrical power outlet in the vehicle but it must be understood that the description is equally applicable to turning on multiple electrical power outlets in the vehicle. The notification may be provided in various ways such as, for example, via an audio message transmitted through a speaker of an infotainment system of the vehicle, via an audible chime, via a text message sent to a personal device, or via the use of a flashing light.

At block 325, a timer is started. In an example implementation, the timer can be a software-based timer that is started by the processor of the electrical power outlet controller system. In one case, a time period for time-out that is provided by the timer may be preset. In another case, the time period may be user-defined such as, for example, by a driver of the vehicle. The preset time out and/or the user-defined timeout may be determined on the basis of various factors such as, for example, a charge capacity and/or a state of charge (SOC) of one or more batteries that can be included in an electrical power source that provides power to the electrical power outlets in the vehicle. Another example factor can pertain to a location of the vehicle at the time one or more of the actions indicated in block 305, block 310, and/or block 315 are carried out. For example, in various example scenarios, the vehicle may be located near a residence, at a work site, or near an electric charging station and the time out period may be set accordingly. Yet another example factor may be an identity of an individual associated with one or more of the actions indicated in block 305, block 310, and/or block 315. For example, a driver of the vehicle may be allocated a first amount of time (time-out period) to operate the power outlet activation switch and a passenger of the vehicle may be allocated a second amount of time that is different than the first amount of time.

At block 330, a determination is made whether the power outlet activation switch has been turned on. If the power outlet activation switch has been turned on, at block 335, the timer is reset, and at block 340, power is coupled into the electrical power outlet. An example operation to couple power to the electrical power outlet is described above with respect to switch 220 and/or switch 245 (shown in FIG. 2).

At block 345, a determination is made whether the electrical power outlet has been left unused over a period of time such as, for example, when the driver has operated the power outlet activation switch and walked away from the vehicle. The determination may be made based on evaluation of one or more images (or a video stream) over a period of time that may be selected based on a timer (another software timer, for example). If the electrical power outlet has been left unused over the period of time, the action indicated at block 370 (described below) is carried out.

If, at block 330, it is determined that the power outlet activation switch has not been turned on, at block 350, a determination is made whether the timer has timed out. If the timer has not timed out, the processor waits for the timer to time out. If the timer has timed out, at block 355, a determination is made whether a person (or a device such as a personal device or key fob) is present in the vicinity of the vehicle (inside a geofence, for example). In an example scenario, the driver may have opened the driver-side door and exited the vehicle but may have become busy with other activities that may have prevented him/her from operating the power outlet activation switch.

If a person is present in the vicinity of the vehicle, at block 360, the time out period of the timer that was started at block 325 is extended and the actions indicated at block 330 and subsequent blocks are executed.

If a person (or a device such as a personal device or key fob) is not present in the vicinity of the vehicle, at block 365, the timer that was started at block 325 is reset. In another example scenario, an alarm of the vehicle may turn active such as, for example, due to a break-in into the vehicle. The alarm may occur either before or after the timer has timed out and/or has been reset. The processor of the electrical power outlet controller system detects and responds to the alarm by executing the actions indicated at block 370 and subsequent blocks.

At block 370, an alert may be issued to inform the driver of the vehicle (for example) that power to the electrical power outlet is about to be disconnected or to inform the driver of the alarm condition.

At block 375, a determination may be made whether a request has been received for retaining power coupled into the electrical power outlet. In an example scenario, the driver may respond to the alert (described above at block 370) by providing a request to retain power provided to the electrical power outlet. The request may be provided in various ways such as, for example, by re-opening and closing a door of the vehicle, or via a GUI of an infotainment system in the vehicle, or via a personal device, or by operating the power outlet activation switch once again. If such a request is received, the actions indicated at block 360, block 330, and subsequent blocks may be carried out.

In some implementations, block 375 may be optional and may be replaced by a block wherein a decision may be made by the processor whether to retain power provided to the electrical power outlet. In an example scenario, the processor may make the decision based on evaluating one or more images. The images may indicate to the processor that an electrical power cord of a device located outside the vehicle is coupled to the electrical power outlet. In this scenario, the actions indicated at block 360, block 330, and subsequent blocks may be carried out. The device located outside the vehicle can be, for example, the lawn mower 130 shown in FIG. 1.

If, at block 375, the determination indicates that no devices are coupled to the electrical power outlet, at block 380, the electrical power outlet is disabled. An example operation to disable the electrical power outlet is described above with respect to switch 220 and/or switch 245 (shown in FIG. 2).

It must be understood that the flowchart 300 represents merely one example embodiment in accordance with the disclosure. In other embodiments, some of the actions and objects described above with reference to the flowchart 300 may be omitted, replaced, or modified. For example, in another embodiment in accordance with the disclosure, the driver 115 of the vehicle 105 may manually activate a switch to energize an electrical power outlet (such as, for example, manually activate the switch 220 shown in FIG. 2 to energize the electrical power outlet 225). The driver 115 may opt to manually activate the switch, for example, when the vehicle 105 is parked inside a garage, a building, a fenced compound, a geofenced area, a worksite, a residence, or any other location that the driver 115 may deem as being a protected environment where the electrical power outlet may not be misused. In yet another embodiment, the driver 115 may provide an instruction (via the personal device 138 or the infotainment system 117) to the electrical power outlet controller system 125 to extend the time-out period of the timer (or to cancel the timer) for any of various reasons. An example reason for extending the time-out period can be directed at allowing the driver 115 to perform some other activities (away from the vehicle 105, for example), before using the electrical power outlet.

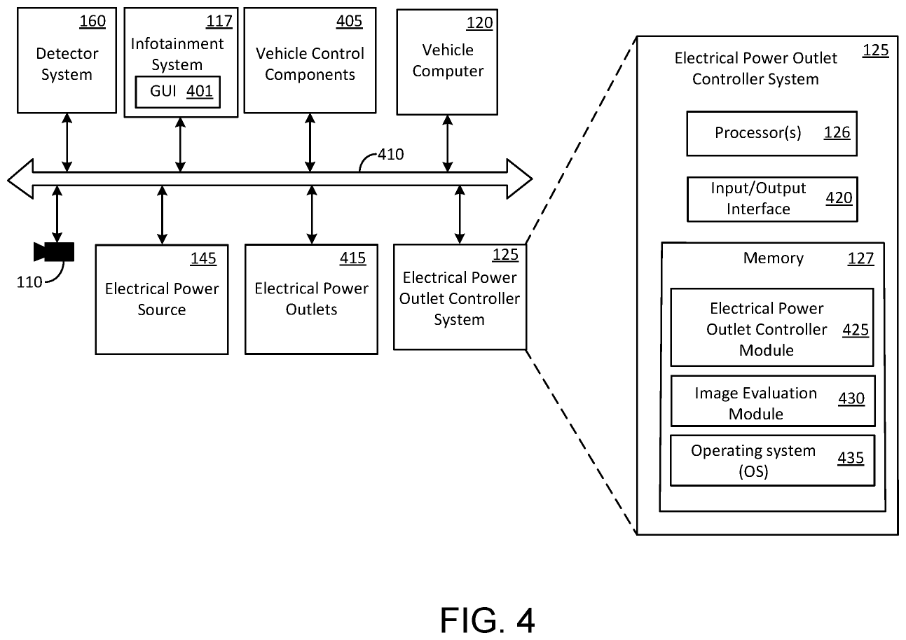

FIG. 4 shows some example components that can be included in the vehicle 105 in accordance with an embodiment of the disclosure. The example components can include the detector system 160, the infotainment system 117, vehicle control components 405, the vehicle computer 120, the camera 110, the electrical power source 145, electrical power outlets 415, and the electrical power outlet controller system 125. The various components are communicatively coupled to each other via one or more buses such as an example a bus 410. The bus 410 may be implemented using various wired and/or wireless technologies. For example, the bus 410 can be a vehicle bus that uses a controller area network (CAN) bus protocol, a Media Oriented Systems Transport (MOST) bus protocol, and/or a CAN flexible data (CAN-FD) bus protocol. Some or all portions of the bus 410 may also be implemented using wireless technologies such as Bluetooth®, Bluetooth®, Ultra-Wideband, Wi-Fi, Zigbee®, or near-field-communications (NFC).

The detector system 160 can include various types of detectors/sensors such as, for example, a door opening detector, a door unlocking detector, a door unlatching detector, a presence detector, and a movement detector. The detection devices may include, for example, a magnetic sensor, a radar detector, a sonar detector, a LIDAR detector, and/or an infrared detector. Some example detectors that are described above and shown in FIG. 2, include the detector 212, the detector 228, and the detector 253. The detector system 160 may further include image capture devices such as, for example, one or more cameras. An example camera 110 (described above and shown in FIG. 1) is shown coupled to the bus 410.

The signals conveyed by the various detectors of the detector system 160 to the electrical power outlet controller system 125 can vary in accordance with the type of detector. For example, the camera 110 can provide an image of the driver 115 (for example) in one of various formats (jpeg, mpeg, etc.), and the detector 228 can provide a digital signal indicating that the cover of the electrical power outlet 225 is either in a closed position or in an open position.

The vehicle control components 405 can include various components and systems associated with driving-related functions of the vehicle 105 as well as with functions that are associated with the electrical power outlet controller system 125. Some example driving-related functions can include the operation of various vehicle components (engine, brakes, accelerator, fuel injection, etc.), and actions such as collision avoidance, automatic braking, and cruise control. The vehicle control components 405 may be controlled, activated, and/or operated by the vehicle computer 120. In some cases, some of the vehicle control components 405 may be controlled, activated, and/or operated by the electrical power outlet controller system 125. For example, the electrical power outlet controller system 125 may utilize some of the vehicle control components 405 to detect the driver 115 and control an operation of a lid of an electrical power outlet.

The infotainment system 117 can include a display system having a GUI 401 for carrying out various operations. The GUI may be used, for example, by the driver 115 of the vehicle 105 to interact with the electrical power outlet controller system 125, for obtaining information about various electrical power outlets in the vehicle 105, and/or for managing the operations of various electrical power outlets in the vehicle 105.

The electrical power outlets 415 can include the various example electrical power outlets described above.

The electrical power outlet controller system 125 can be implemented in various ways. In one example implementation, the electrical power outlet controller system 125 can be an independent device (enclosed in an enclosure, for example). In another example implementation, some or all components of the electrical power outlet controller system 125 can be housed, merged, or can share functionality, with the vehicle computer 120. For example, an integrated unit that combines the functionality of the electrical power outlet controller system 125 with that of the vehicle computer 120 can be operated by a single processor and a single memory device. In the illustrated example configuration, the electrical power outlet controller system 125 includes the processor 126, an input/output interface 420, and a memory 127.

The input/output interface 420 is configured to provide communications between the electrical power outlet controller system 125 and other components coupled to the bus 410, for example.

The memory 127, which is one example of a non-transitory computer-readable medium, may be used to store an operating system (OS) 435, an image evaluation module 430, and various code modules such as, for example, an electrical power outlet controller module 425. The code modules are provided in the form of computer-executable instructions that can be executed by the processor 126 for performing various operations in accordance with the disclosure.

The electrical power outlet controller module 425 may be executed by the processor 126 for performing various operations in accordance with the disclosure. Some example operations are described above with reference to the flowchart 300. Execution of some of these operations can involve the electrical power outlet controller module 425 utilizing the image evaluation module 430 for evaluating images captured by a camera such as, for example, the camera 110.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, one skilled in the art will recognize such feature, structure, or characteristic in connection with other embodiments whether or not explicitly described.

Implementations of the systems, apparatuses, devices, and methods disclosed herein may comprise or utilize one or more devices that include hardware, such as, for example, one or more processors and system memory, as discussed herein. An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or any combination of hardwired or wireless) to a computer, the computer properly views the connection as a transmission medium. Transmission media can include a network and/or data links, which can be used to carry desired program code means in the form of computer-executable instructions or data structures and which can be accessed by a general purpose or special purpose computer. Combinations of the above should also be included within the scope of non-transitory computer-readable media.

Computer-executable instructions comprise, for example, instructions and data which, when executed at a processor, cause the processor to perform a certain function or group of functions. The computer-executable instructions may be, for example, binaries, intermediate format instructions, such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

A memory device, such as the memory 127, can include any one memory element or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, the memory device may incorporate electronic, magnetic, optical, and/or other types of storage media. In the context of this document, a “non-transitory computer-readable medium” can be, for example but not limited to, an electronic, magnetic, optical, electromagnetic, infrared, or semiconductor system, apparatus, or device. More specific examples (a non-exhaustive list) of the computer-readable medium would include the following: a portable computer diskette (magnetic), a random-access memory (RAM) (electronic), a read-only memory (ROM) (electronic), an erasable programmable read-only memory (EPROM, EEPROM, or Flash memory) (electronic), and a portable compact disc read-only memory (CD ROM) (optical). Note that the computer-readable medium could even be paper or another suitable medium upon which the program is printed, since the program can be electronically captured, for instance, via optical scanning of the paper or other medium, then compiled, interpreted or otherwise processed in a suitable manner if necessary, and then stored in a computer memory.

Those skilled in the art will appreciate that the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description, and claims refer to particular system components. As one skilled in the art will appreciate, components may be referred to by different names. This document does not intend to distinguish between components that differ in name, but not function.

It should be noted that the detector embodiments discussed above may comprise computer hardware, software, firmware, or any combination thereof to perform at least a portion of their functions. For example, a detector may include computer code configured to be executed in one or more processors and may include hardware logic/electrical circuitry controlled by the computer code. These example devices are provided herein for purposes of illustration and are not intended to be limiting. Embodiments of the present disclosure may be implemented in further types of devices, as would be known to persons skilled in the relevant art(s).

At least some embodiments of the present disclosure have been directed to computer program products comprising such logic (e.g., in the form of software) stored on any computer-usable medium. Such software, when executed in one or more data processing devices, causes a device to operate as described herein.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described example embodiments but should be defined only in accordance with the following claims and their equivalents. The foregoing description has been presented for the purposes of illustration and description. It is not intended to be exhaustive or to limit the present disclosure to the precise form disclosed. Many modifications and variations are possible in light of the above teaching. Further, it should be noted that any or all of the aforementioned alternate implementations may be used in any combination desired to form additional hybrid implementations of the present disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method comprising:
determining, by a processor in a vehicle, that the vehicle is in a key-off state;
detecting, by the processor, at least one of a first door of the vehicle being opened or the first door being unlocked by use of a passive entry device; and
providing, by the processor, a first time period to allow an individual to energize an electrical power outlet in the vehicle after the first door is one of opened or unlocked and the vehicle is in the key-off state.

2. The method of claim 1, wherein the first door is a driver-side door of the vehicle, the individual is a driver of the vehicle, wherein the passive entry device is one of a key fob or a personal device, and wherein energizing the electrical power outlet comprises operating a switch to couple an electrical power source to the electrical power outlet.

3. The method of claim 2, wherein the first time period is a user-definable time period.

4. The method of claim 2, further comprising:
disconnecting, by the processor, the electrical power outlet from the electrical power source based on at least one of detecting a failure of the individual to operate the switch within the first time period or detecting a movement of the individual outside a boundary defined around the vehicle.

5. The method of claim 4, wherein detecting the movement of the individual outside the boundary defined around the vehicle comprises evaluating, by the processor, an image captured by a camera provided on the vehicle.

6. The method of claim 4, further comprising:
reconnecting, by the processor, the electrical power outlet to the electrical power source based on detecting at least one of the first door of the vehicle being re-opened, a second door of the vehicle being opened, or a presence of the individual inside the boundary defined around the vehicle.

7. The method of claim 1, further comprising:
extending, by the processor, the first time period based on at least one of detecting a presence of the individual inside a boundary defined around the vehicle or upon evaluating an image and detecting that an electrical power cord of a device located outside the vehicle is plugged into the electrical power outlet.

8. The method of claim 7, wherein energizing the electrical power outlet comprises operating a switch to couple a battery of the vehicle to the electrical power outlet, and wherein the method further comprises:
issuing, by the processor, an alert upon at least one of an expiration of a second period of time or detecting a charge level of the battery dropping below a threshold charge; and
disconnecting, by the processor, the battery from the electrical power outlet after a wait period has expired since issuing of the alert.

9. A method comprising:
determining, by a processor in a vehicle, that the vehicle is in a key-off state;
detecting, by the processor, at least one of an individual exiting from an interior portion of the vehicle, the individual accessing the interior portion of the vehicle from outside the vehicle; or a presence of a passive entry device within a threshold distance of the vehicle; and
providing, by the processor, a first time period to allow the individual to activate a switch to couple electrical power to an electrical power outlet provided in the vehicle and accessible from outside the vehicle.

10. The method of claim 9, wherein detecting the individual exiting from the interior portion of the vehicle comprises:
detecting, by the processor, a first door of the vehicle being opened by the individual.

11. The method of claim 10, wherein the first door is a driver-side door of the vehicle, wherein the individual is a driver of the vehicle, wherein the passive entry device is one of a key fob or a personal device, and wherein coupling the electrical power to the electrical power outlet comprises activating the switch to couple a battery of the vehicle to the electrical power outlet.

12. The method of claim 9, wherein at least one of the first time period or the threshold distance is definable by the individual, and wherein the method further comprises:
receiving, by the processor, from a camera provided on the vehicle, an image that includes the individual;
determining, by the processor, based on evaluating the image that the individual is carrying the passive entry device and is located within the threshold distance of the vehicle; and
retaining, by the processor, the electrical power outlet in a powered-up state beyond the first time period based on determining that the individual is carrying the passive entry device and is located within the threshold distance of the vehicle.

13. The method of claim 9, wherein at least one of the first time period or the threshold distance is definable by the individual, and wherein the method further comprises:
receiving, by the processor, from a security system of the vehicle, an alarm during the first time period; and
disconnecting, by the processor, the electrical power coupled to the electrical power outlet.

14. The method of claim 13, further comprising:
reconnecting, by the processor, the electrical power to the electrical power outlet upon detecting at least one of a door of the vehicle being opened or a cancellation of the alarm.

15. A vehicle comprising:
a vehicle controller;
a detector system; and
a parking assistance system comprising:
a memory that stores computer-executable instructions; and
a processor configured to access the memory and execute the computer-executable instructions to perform operations comprising:
determining, based on information received from the vehicle controller, that the vehicle is in a key-off state;
detecting, based on information received from the detector system, at least one of a first door of the vehicle being opened or the first door being unlocked by use of a passive entry device; and
providing a first time period to allow an individual to energize an electrical power outlet in the vehicle after the first door is one of unlocked or opened.

16. The vehicle of claim 15, further comprising a switch operable to couple an electrical power source to the electrical power outlet, and an image capture system comprising a camera configured to capture an image of at least one of the individual or the passive entry device carried by the individual.

17. The vehicle of claim 16, wherein the processor is configured to access the memory and execute the computer-executable instructions to perform further operations comprising:
disconnecting the electrical power outlet from the electrical power source based on at least one of detecting a failure of the individual to operate the switch within the first time period or detecting a movement of the individual outside a boundary defined around the vehicle, wherein the at least one of detecting the failure of the individual to operate the switch or detecting the movement of the individual outside the boundary defined around the vehicle comprises evaluating the image received from the camera.

18. The vehicle of claim 16, wherein the processor is configured to access the memory and execute the computer-executable instructions to perform further operations comprising:
retaining the electrical power outlet in an energized condition beyond the first time period based on evaluating the image received from the camera, the evaluating comprising at least one of detecting a presence of the individual inside a boundary defined around the vehicle or detecting a usage of the electrical power outlet to power a device located outside the vehicle.

19. The vehicle of claim 16, wherein the first time period is definable by the individual, and wherein the processor is configured to access the memory and execute the computer-executable instructions to perform further operations comprising:
detecting an activation of the switch within the first time period; and
coupling the electrical power source to the electrical power outlet based on the activation of the switch within the first time period.

20. The vehicle of claim 15, further comprising a security system, and wherein the processor is configured to access the memory and execute the computer-executable instructions to perform further operations comprising:
receiving from the security system, an alarm during the first time period; and
disconnecting, electrical power coupled to the electrical power outlet based on receiving the alarm.
